(19) United States
(12) Patent Application Publication
(10) Pub. No.: US 2026/0084189 A1
(43) Pub. Date: Mar. 26, 2026

(54) YIELD IMPROVEMENT SYSTEM FOR DIE STACK FLUX REMOVAL

(71) Applicant: VEECO INSTRUMENTS INC., Plainview, NY (US)

(72) Inventors: Hunter Jones, Eagleville, PA (US); Phillip Tyler, Ann Arbor, MI (US); John Taddei, Marco Island, FL (US); Robert Edwards, Montgomeryville, PA (US); Mark Yannuzzi, Warminster, PA (US); Kevin Donnelly, Abington, PA (US)

(73) Assignee: VEECO INSTRUMENTS INC., Plainview, NY (US)

(21) Appl. No.: 19/334,185

(22) Filed: Sep. 19, 2025

Related U.S. Application Data
(60) Provisional application No. 63/698,250, filed on Sep. 24, 2024.

(51) Int. Cl. B08B 3/08; B08B 3/02; B08B 3/10

(52) U.S. Cl. CPC B08B 3/08; B08B 3/02; B08B 3/10; H10P 70/20

(57) ABSTRACT

A system for improving yield and increasing throughput on processes that remove flux and flux residues from openings between 3D semiconductor structures. The system employs high flow, directed, pressurized nitrogen to assist in de-wetting the areas between semiconductor devices where solder bumps or micro bumps attach one device to another.

### CROSS REFERENCE TO RELATED APPLICATION

The present application claims priority to U.S. Application No. 63/698,250, filed Sep. 24, 2024, which is hereby incorporated by reference in its entirety. The present application is also related to U.S. Pat. No. 11,756,805 B2 (Apparatus and Method for Die Stack Flux Removal), which is also hereby incorporated by reference in its entirety.

### TECHNICAL FIELD

The present disclosure generally relates to an apparatus and method for removal of flux and flux residues. More specifically, the present disclosure relates to an apparatus and method for enhancing yield and throughput for processes that remove flux and flux residues from a device bonded to other devices or substrates via connections that include bumps and micro bumps.

### BACKGROUND

In recent years, 3D packaging designs were developed for high bandwidth memory (HBM) die stacks. These die stacks consist of multiple dies bonded together in a vertical fashion. Electrical connections are formed through the utilizing through silicon vias (TSV) and from die to die with microbumps. The industry standard is stacking 8-12 die high with future targets of 16 or more die. Other packaging designs were developed for attaching these HBM stacked die in proximity to logic and other HBM die on a substrate. These designs included bonding a memory stack on top of a logic die and another design locating logic and die stacks in proximity on the same plane. These variations had versions that included and excluded interposers. The interposer tradeoff was performance versus reduced form factor for mobile devices. Interposers include an additional layer, which adds thickness, and makes it too thick for a mobile device at the moment. The use of an interposer is typically utilized in such applications as high-performance computing and artificial intelligence. These packaging techniques connected memory/logic die, interposer and substrate through the use of solder bumps\micro bumps of varying size and spacing. Post bonding, the bumps required a flux and flux residue clean to remove any residual material that if left in place would reduce performance and yield. Advancements in semiconductor wet processes and single wafer wet process tool design enabled chip manufacturers to obtain high yield on the mass production of 3D packaging to market these new devices for AI, datacenters and high-performance mobile devices. U.S. Pat. No. 11,756,805 B2 (Apparatus and Method for Die Stack Flux Removal) is an example of such innovation. Process development in many cases came by extending process times and while increasing yield, decreased throughput. Demand has skyrocketed for the new high-performance devices. At the same time, 3D design continues to evolve. HBM stacks are increasing in height from 8-12 stacked die to stacks of 16 die or more. The evolution in heterogenous packaging to combine memory and logic is also adding additional capability through vertical methods by adding layers and additional components to the design.

As always, semiconductor (and therefore bump) dimensions shrink and pitches get tighter to boost performance while reducing the size of the product. The need to effectively remove flux and flux residues post bonding becomes more challenging. Accordingly, there is a need to boost yield and increase throughput in legacy products and designs for the next generation geometries. Advancements in the art of wet processes were required in the marketplace to ensure technological growth.

### SUMMARY

In one embodiment, an apparatus and method to increase throughput and yield on processes that remove flux and flux residues from 3D packages, such as die stack and chip on wafer technologies. The baseline process for removing flux and flux residues from 20-micron pitch micro bumps historically consist of a four-station system—1) solvent immersion, 2) solvent spin spray, 3) rinse fluid immersion and 4) spin rinse dry stations. The solvent spray station historically receives a solvent covered wafer from the solvent immersion station and employs several liquid dispenses at advantageous angles, pressures and nozzle types, while the wafer is rotated to extreme ranges to assist in wetting and de-wetting the bumps. While die stacks at a radius far from center had high centripetal forces from the spinning substrate (wafer, panel, etc.), the area near the center has smaller centripetal forces. The center area is dependent on the high-pressure liquid enabling sufficient solvent fluid exchange within the die stack. The invention adds an additional medium pressure, high flow heated nitrogen dispense system into the solvent spin chamber.

In one embodiment, the disclosed system has the following operating parameters: nitrogen is injected at medium pressure (80-130 psi) with flow (50-500 SLPM, optimal 265 SLPM) at an angle of (0 to 90 degrees with optimal results at 25 degrees) at a height above the substrate of 0.1 to 1.1 inches, optimal at ⅜ inch using a recipe definable arm scan (linear or hyperbolic motion <1 to 6 inches\sec with definable acceleration deacceleration-optimal linear at 24.4 mm\sec), and a chuck rotational speed from 0 to 3000 RPM (optimal when rpm cycles during recipe 150 to 1500). Interchangeable nozzles can vary dispense shape, such as cone, fan, stream. Likewise, orifice openings in the dispense nozzle can vary (e.g., 0.24 inch for round nozzle has optimal performance in at least one embodiment). This aggressive nitrogen dispense is employed to remove flux cleaning chemistry from within the bump array. It has enabled a reduction in process times through more effectively dislocating flux contaminated solvent from within the bumps of the stack. This subsequently enables access for fresh solvent to enter the die stack or in the case at the end of the solvent spin process, remove contamination and any residual solvent to shorten solvent spin processing time. A second high flow N2 dispensing arm located in the SRD chamber serves to shorten rinse times and increase rinse effectiveness by dislocating the IPA or other fluid in the same fashion the first high flow N2 arm was utilized in the solvent spin chamber. The addition of high flow N2 into the solvent and SRD chambers has enabled increased throughputs and improved yields (with the biggest yield boost being near the wafer center) through enabling faster and more complete fluid vacating of the areas in and around the bump structures.

In an additional embodiment, other geometries of bumps permit all solvent, all rinse and spin dry to be completed in a single spin chamber. This situation permits a single high flow N2 arm to conduct both post solvent and post rinse type fluid evacuation sequences.

### BRIEF DESCRIPTION OF THE DRAWING FIGURES

FIG. 1 is a top plan view of a wafer showing a center portion where yield is most likely to be adversely impacted;

FIG. 2 is a top and side perspective view of an exemplary spin processing chamber including a dispensing arm in accordance with one embodiment;

FIG. 3 is a side perspective view of the dispensing arm;

FIG. 4 is a top perspective view of the dispensing arm in a retracted, stored away position;

FIG. 5 is a top perspective view of the dispensing arm in an active, exposed position;

FIG. 6 is a schematic showing a plumbing hardware path for dispensing the fluid (e.g., gas) through the dispensing arm;

FIG. 7 is a top and side perspective view of the spin processing chamber;

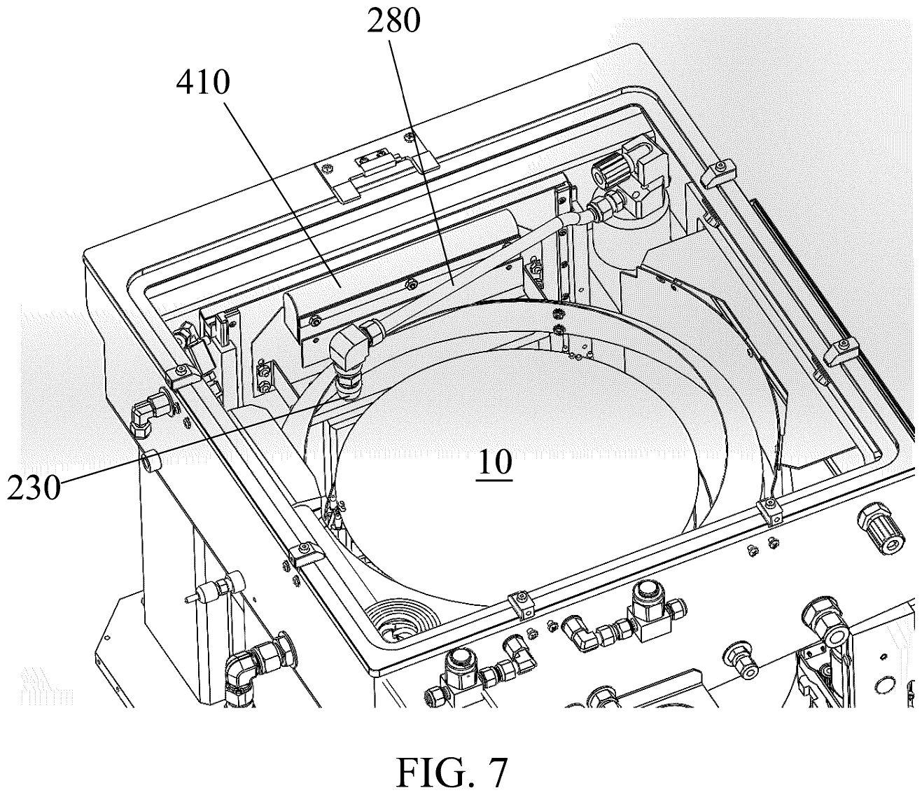

FIG. 8 is a top and side perspective view of the spin processing chamber; and

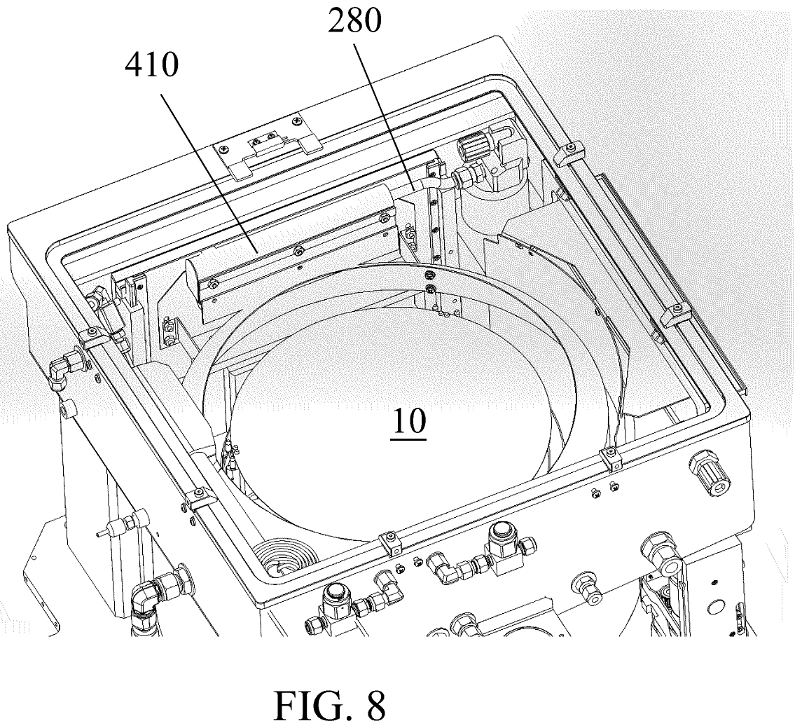

FIG. 9 is a top and side perspective view of the spin processing chamber without the optional arm cover.

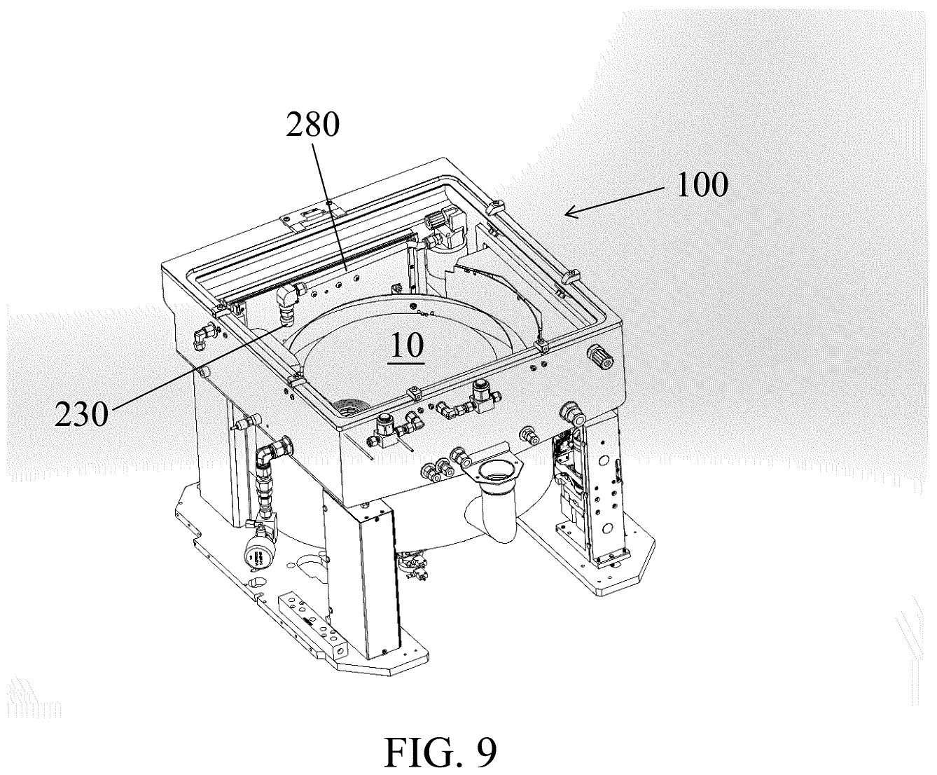

### DETAILED DESCRIPTION OF CERTAIN EMBODIMENTS

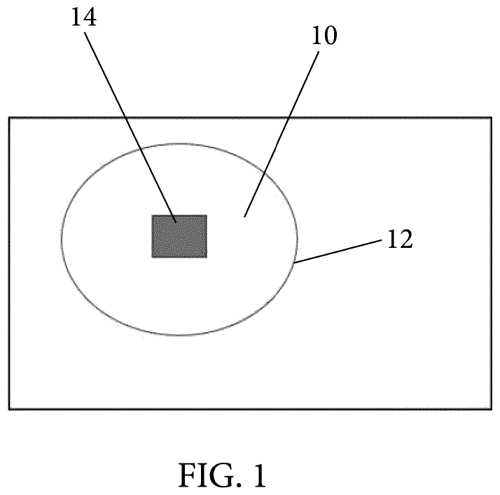

FIG. 1 illustrates a wafer 10 that includes a peripheral edge 12 and a center portion (section) 14. As described hereinbefore, it is the center portion 14 that represents the location where yield is most likely to be impacted when using traditional cleaning technqiues and equipment. The center portion 14 can be thought of as being a process defect point which has a buildup of undesired materials, such as flux and flux residues.

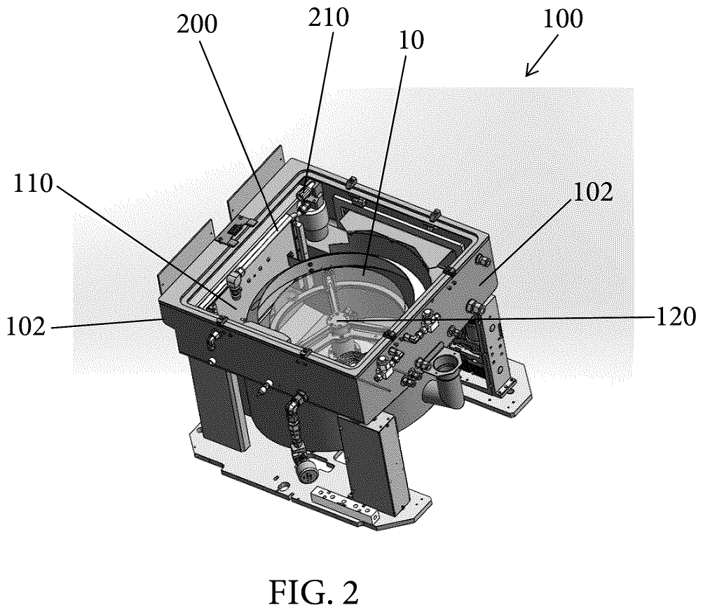

FIG. 2 illustrates a spin processing chamber 100 that is typically part of a wafer processing system. The system can be a system configured to remove flux and flux residues from 3D packaging, such as die stack and chip on wafer technologies. In one exemplary method, an initial step is to subject the wafer to flux removal fluid (chemistry) as by placing the wafer in an immersion bath for a period of time where agitation, ultrasonic energy and\or fluid recirculation through the bath will assist in fluid flow through device openings.

The substrate is then transferred wet to a spin station (subsequent step) to complete the flux removal portion of the process. A combination of high-pressure and low-pressure flux removal fluid will be used to further force fluid movement through the small openings in the devices. It should be noted this may or may not be the same fluid as in the immersion station.

The spin processing chamber 100 is part of the spin station. As shown, the spin processing chamber 100 comprises a tank with a hollow interior inside of side walls 102. The spin processing chamber 100 has numerous parts that deliver and remove fluids as described in the '805 patent.

High pressure (up to 3,000 psi) or high velocity spray nozzles can be oriented in a low angle (0 to <45 degree) spray orientation to direct spray at the device openings. An arm scan across the substrate from edge to edge and by reversing spin direction provides superior fluid flow through the areas to remove the flux. This spray may be done at a number of pressure settings, and potentially while changing substrate RPM. Cycling spin chuck RPM and using low pressure, high volume dispenses assist in flowing flux removal chemistry through the device openings in order to remove dirty and saturated flux removal chemistry. Rinsing is accomplished through the use of clean low surface tension fluid to displace the flux removal fluid. The similar dispense type cycling (high pressure\high velocity at low angle and high volume/low pressure) and chuck RPM cycling to entice sufficient fluid through the devices to displace as much flux removal fluid with low surface tension rinse fluid as possible.

The substrate in some cases can be transferred to an immersion station filled with the rinsing fluid. Agitation, ultrasonic energy and\or fluid recirculation can be used to entice fluid flow through package openings to remove any flux removal chemistry or other contaminants. All immersion stations (flux removal or rinse stations) have multi-substrate capability and it is process dependent if one or more substrates are in the station concurrently.

Post rinse immersion the wafer can return to the spin station to repeat high pressure\high velocity spray and low pressure dispense cycles of low surface tension rinse fluid, while varying RPM of the substrate. This RPM cycling is required to fully rinse out solvent and eliminate staining from solvents during dry. The substrate will then be spun dry. Spin dry can be done with the assistance of a nitrogen source (optionally heated). The nitrogen source needs to in oriented at the small openings between the die in order to maximize nitrogen flow between the die for drying.

The hollow interior 110 of the spin processing chamber 100 thus holds the wafer 10 and includes a spin chunk 120 for controllably rotating the wafer 10. The spin chuck 120 that supports the wafer 10, which is centrally positioned on the spin chuck. The wafer 10 can be a 300 mm wafer that suffers from reduced yield in the center portion 14.

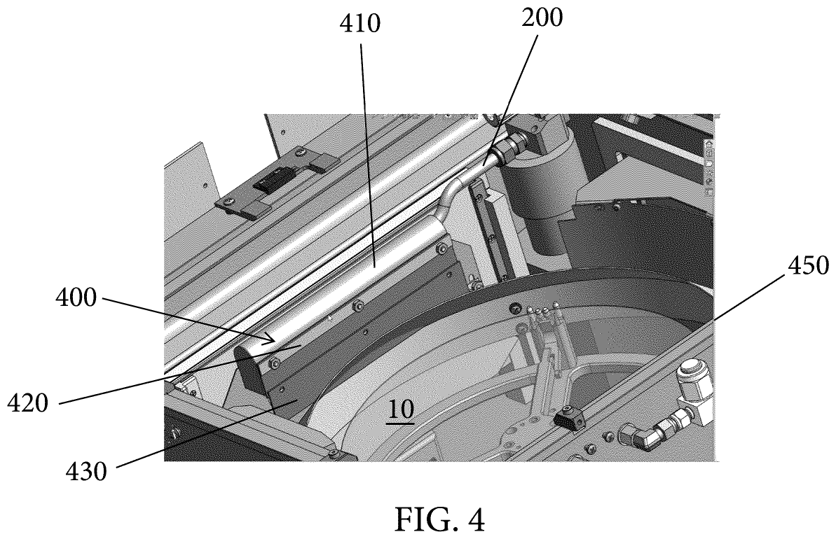

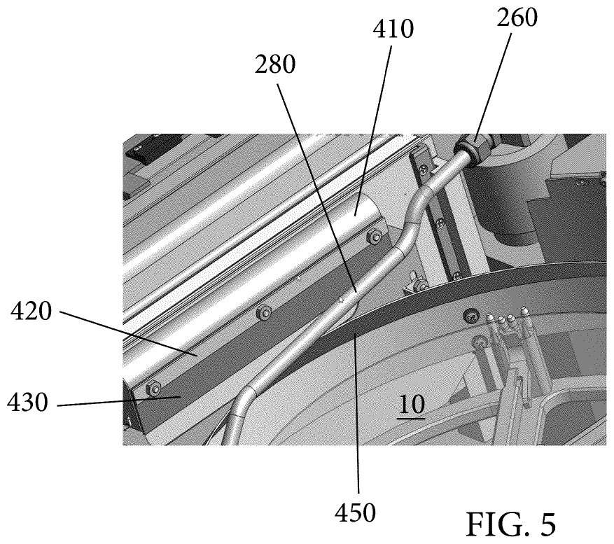

In accordance with the present disclosure, a dispensing arm 200 is provided as part of the spin processing chamber 100 and more specifically, the dispensing arm 200 is positioned along one side wall 102. The dispensing arm 200 can be considered to be and be labeled as a cyclone yield boost arm. As described herein, the dispensing arm 200 moves between a retracted, stored away position (FIG. 4) and an active, exposed position (FIG. 5). The dispensing arm 200 dispenses fluid, such as a drying gas, such as nitrogen (N2). The dispensing arm 200 moves about an axis that is generally located in one corner of the spin processing chamber 100. The dispensing arm 200 rotates about this axis and also the dispensing arm 200 can move up and down along this axis. The rotation of the dispensing arm 200 allows the dispensing arm 200 to move in a sweeping action above the wafer 10.

It will be appreciated that instead of using nitrogen gas as the drying aid, the nitrogen gas can be substituted with an alternative gas, examples of which are clean dry air (CDA), helium and carbon dioxide. Moreover, while in one preferred embodiment, the dispensed fluid is gaseous nitrogen gas, this gas can be substituted with a liquid that when dispensed shall turn into a gas under the conditions within the spin processing chamber 100. One example of such a fluid is liquid CO2.

The dispensing arm 200 has a fluid inlet generally indicated at 210 that is configured to fluidly connect to fluid plumbing for delivering the fluid to the dispensing arm 200. In the case in which the dispensing arm 200 comprises a nitrogen dispensing arm, the inlet 210 comprises an N2 inlet which connects to N2 plumbing (not shown).

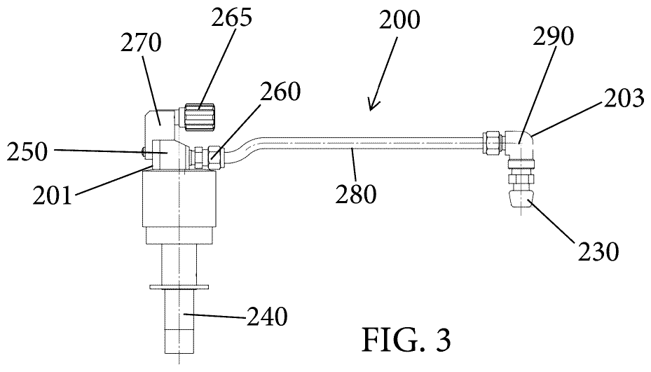

FIG. 3 illustrates in more detail the dispensing arm 200. The dispensing arm 200 includes a nozzle 230 (a dispense nozzle and housing) at one end through which the fluid (e.g. nitrogen gas) is dispensed. It will be appreciated that the nozzle 230 is shown at a 90-degree angle, perpendicular to the substrate surface; however, this orientation is not the most effective for a baseline chip on wafer flux removal process. Thus, it will be appreciated and is within the scope of the disclosure that the nozzle 230 can be positioned at angles other than 90 degrees (e.g., angles less than 90 degrees, e.g., angles less than 45 degrees, e.g., 25 degrees). It will be appreciated that these angles are only exemplary in nature and are not limiting.

The dispensing arm 200 is coupled to a first (skirted) drive arm 240 which defines the axis about which the dispensing arm 200 rotates and can also move up and down. The first (skirted) drive arm 240 provides coupling of the dispensing arm 200 to a second main drive arm (not shown). The second main drive arm is operatively coupled to a drive source, such as a motor. A top section of the first (skirted) drive arm 240 can be enlarged and provides a surface on which the dispensing arm 200 is mounted. This top section can be cylindrical in shape and the first (skirted) drive arm 240 can also be cylindrical in shape.

As shown, the dispensing arm 200 is an elongated structure defined by a proximal end 201 and an opposite distal end 203. The nozzle 230 is located at the distal end 203. The proximal end 201 is the end at which the fluid connection is made. More specifically, the dispensing arm 200 includes a housing 250 that can be coupled to and sit along the top surface of the top section of the first (skirted) drive arm 240. A fluid source connection (first connector) 265 is provided and can be coupled to the housing 250 as shown. An arm lock 270 serves to lock the fluid source connection 260 in place. The fluid source connection 260 is fluidly connected to a fluid source, such as a nitrogen gas source that delivers nitrogen gas to the dispensing arm 200.

The housing 250 is also fluidly coupled to a connector 260 which serves to attach an elongated shaft 280 of the dispensing arm 200. As shown, one end (proximal end) of the shaft 280 connects to the housing 250.

The shaft 280 can be a linear or substantially linear hollow conduit that carries the fluid (e.g., nitrogen gas); however, it can take other shapes and/or include one or more bent or curved sections that connect two or more linear sections. As mentioned, at the distal end of the shaft 280, the nozzle 230 is located. The nozzle 230 can be formed of two or more parts. For example, as shown, the nozzle 230 can have a two-part construction in that the nozzle 230 can be coupled to the shaft 280 by a dispense connector 290. This type of arrangement allows for the nozzle 230 itself to be detached and interchanged with a different type of nozzle 230. In addition, the dispense connector 290 can also be detached and interchanged with another one. This level of detachment and interchangeability of the one or more nozzle parts allows for the nozzle angle to be easily changed by swapping out parts.

The housing 250 and connector 260 lie below the arm lock 270 and the fluid source connection 265. The major longitudinal axis of the shaft 280 is perpendicular to the axis of the first (skirted) drive arm 240 and extends radially outward from the first (skirted) drive arm 240. The length of the shaft 280 is selected in view of the dimensions of the spin processing chamber 100 and/or the dimensions of the wafer 10. The length of the shaft 280 is selected for positioning the nozzle at a distance from the rotation axis to permit a proper sweeping action and proper coverage over the wafer 10.

FIGS. 4 and 5 show different positions of the dispensing arm 200 within the spin processing chamber 100. FIG. 4 shows the dispensing arm 200 in a retracted, stored away position, while FIG. 5 shows the dispensing arm in an active, exposed position. The spin processing chamber 100 includes an arm cover 400 that is configured to shield the dispensing arm 200 from fluids (liquids) that are used during the cleaning process. The arm cover 400 is located along the same side wall on which the dispensing arm 200 is located. The arm cover 400 includes an upper section 410, a connector 420 and a lower fluid guard 430. The arm cover 400 defines a hollow interior that acts as an arm storage compartment and is configured to receive the dispensing arm 200. It will be appreciated that one end of the arm cover 400 is open to permit travel of the dispensing arm 200 into and out of the the arm cover 400. As shown in FIG. 4, the bend in the shaft 280 permits a proximal section of the shaft 280 to lie above the arm cover 400, while the intermediate and distal sections of the shaft 280 lie within (underneath) the arm cover 400.

The bottom of the arm cover 400 is completely open to allow the dispensing arm 200 to be lowered out of the arm cover 400 and subsequently raised into the hollow interior of the arm cover 400. The upper section 410 represents the ceiling of the arm storage compartment. The illustrated upper section 410 can have a curved shape (dome shaped).

As mentioned, FIG. 4 shows the dispensing arm 200 parked under the arm cover 400. The majority of fluids sprayed onto the wafer 10 will be directed down to the lower areas of the spin chamber via a splash shield 450. The arm cover 400 is intended to keep solvent or rinse fluids that pass above the splash shield 450 from coming into contact with the portion of the dispensing arm 200 that travels above the wafer 10 when the dispensing arm 200 is in use. In other words, the arm cover 400 is intended to keep the dispensing arm 200 at least substantially dry as process steps are performed.

It will be understood that the arm cover 400 is optional.

FIG. 5 shows the dispensing arm 200 after passing from under the arm cover 400 to its use position for use above the splash shield 450 and above the wafer 10.

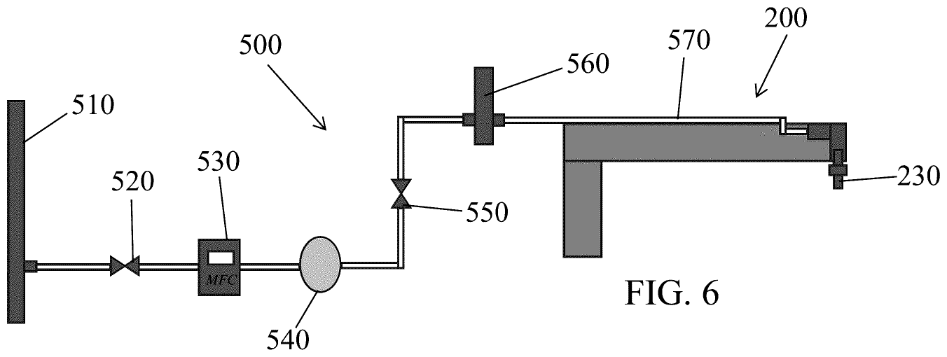

FIG. 6 shows an exemplary plumbing hardware path, generally indicated at 500, for the fluid (e.g., nitrogen) dispense and in particular, shows the fluid path from the fluid source to the dispensing arm 200. Nitrogen at constant regulated pressure is delivered to a (tool) bulkhead connector 510 of the tool. An automated valve 520 gates flow to a mass flow controller (MFC) 530 which supplies continuous flow through a 3 nm filter 540 at a steady volume through a second valve 550 that gates flow to a chamber bulkhead connector 560. A tubing path (a conduit) 570 delivers the fluid (e.g., N2) from the chamber wall to the dispensing arm 200, where the fluid (e.g., N2) exits from the dispense nozzle 230.

In addition, the dispensing arm 200 can be employed for assisting the efficiency of fluid removal under and between die and 3D structures in solvent only, rinse fluid only or combined solvent, rinse and spin chambers with one or more high flow nozzles.

The high flow dispensing arm 200 can be used for 3D structures bonded to wafers, panels and circuit boards of varying sizes semi standard or non-standard dimensions. The system and high flow dispensing arm disclosed herein are beneficial to meet a number of environmental, societal, and governance (ESG) goals through enabling more efficient processing of devices to producing a higher number of yielding devices, while reducing resources utilized and reducing waste volumes. In one embodiment, the high flow N2 gas can be dispensed in a pattern that traces the edge of interposer or die edges to displace fluid from between and surrounding the bumps (3D structures of the device).

It will also be appreciated that a heater can placed along the fluid path for heating the fluid to promote better drying. Any number of conventional heaters can be used and the heater would be placed upstream of the filter 540 so that the heated fluid passes through the filter 540 before entering dispensing arm 200.

### EXAMPLE

In one exemplary embodiment, the system and dispensing arm 200 operate at the following specifications:

Nitrogen is injected at medium pressure (80-130 psi) with flow (50-500 SLPM, optimal 265 SLPM) at an angle of (0 to 90 degrees with optimal results at 25 degrees) at a height of (0.1 to 1.1 inches, optimal at ⅜ inch) using a recipe definable arm scan (linear or hyperbolic motion up to 6 inches\sec with definable acceleration\deacceleration—optimal linear at 24.4 mm\sec), and a chuck rotational speed from 0 to 3000 RPM (optimal when rpm cycles during recipe 150 to 1500). As mentioned previously, interchangeable nozzles can vary the dispense shape, such as cone, fan, stream, of the dispensed fluid (e.g., nitrogen). Orifice openings in the dispense nozzle 230 can vary (e.g., optimal 0.24 inch for a round stream nozzle).

During the dispensing operation (e.g., N2 dispense), the wafer 10 can be spinning during the high flow dispense (e.g., high flow N2 dispense) or in an alternative embodiment, the wafer can be in a fixed position (no chuck rotation).

It will be understood that the above dimensions are merely exemplary in nature and represent one embodiment, while other dimensions and operating specifications are equally possible.

It is to be understood that the figures and descriptions of the present invention have been simplified to illustrate elements that are relevant for a clear understanding of the present invention, while eliminating, for the purposes of clarity, many other elements which may be found in the present invention. Those of ordinary skill in the pertinent art will recognize that other elements are desirable and/or required in order to implement the present invention. However, because such elements are well known in the art, and because such elements do not facilitate a better understanding of the present invention, a discussion of such elements is not provided herein.

1. A system for removing flux from a substrate that has openings formed therein comprising:
a spin processing chamber that includes a high flow fluid dispensing arm that is fluidly connected to a source of fluid and includes at a distal end a nozzle that is angled for delivering a controlled pressure and volume of fluid for efficient removal of fluid in and around 3D structures of semiconductor devices in order to boost yield and throughput of flux and flux residue removal processes.

2. The system of claim 1, wherein the 3D structures comprise one of: 50-200 micron bumps, 10-30-micron micro bumps and <5 micron nano bumps connecting HBM die or HBM die stacks and other devices such as logic die.

3. The system of claim 2, wherein the die and devices being connected via bumps can be vertically stacked, located in proximity of the same plane as other stacked or non-stacked die.

4. The system of claim 1, wherein the 3D structures can be connected with or without the use of interposers.

5. The system of claim 1, further including a chuck for supporting the substrate, the chuck operating at a rotational speed from 0 to 3000 RPM.

6. The system of claim 5, wherein the angle is 25 degrees.

7. The system of claim 1, wherein the nozzle comprises a detachable and interchangeable nozzle assembly.

8. The system of claim 7, wherein the nozzle is configured to dispense fluid that has a shape selected from the group consisting of: a cone, a fan, and a stream.

9. The system of claim 1, wherein the high flow fluid dispensing arm is fluidly connected to the source of fluid along a fluid flow path that includes a tool bulkhead connector that is in fluid communication with the source of fluid, an automated first valve that is downstream of the tool bulkhead connector and gates flow of the fluid to a mass flow controller (MFC), and a filter downstream of the MFC for filtering the fluid before it flows through a second valve that gates flow to a chamber bulkhead connector that is in fluid communication with an inner conduit of the high flow fluid dispensing arm for delivering the fluid to the nozzle.

10. The system of claim 9, further including a heater for heating the fluid prior to delivery to the filter.

11. The system of claim 1, wherein the high flow fluid dispensing arm can be raised and lowered and can pivot about an axis to allow a sweeping action and placement of the nozzle relative to the substrate.

12. The system of claim 1, further including an arm cover disposed along one wall of the spin processing chamber and being configured to receive and cover the high flow dispensing arm to protect the high flow dispensing arm from liquid spray generated during another process performed in the spin processing chamber.

13. The system of claim 12, wherein the high flow dispensing arm moves between a raised, covered position for shielding the high flow dispensing arm from liquid and a lowered uncovered position in which the high flow dispensing arm is free to rotate and be positioned relative to the substrate.

14. The system of claim 1, wherein the high flow dispensing arm includes a skirted drive arm about which the high flow dispensing arm rotates, the high flow dispensing arm including a housing that is located along an upper face of the skirted drive arm, the high flow dispensing arm including a shaft that is coupled at a proximal end to the housing via a connector and is coupled at a distal end to the nozzle.

15. The system of claim 14, wherein the high flow dispensing arm includes a fluid source connection and an arm lock coupled to the fluid source connection.

16. The system of claim 1, wherein the nozzle is at 25-degree angle.

17. The system of claim 1, wherein the high flow dispensing arm can be employed for assisting the efficient of fluid removal under and between die and 3D structures in solvent only, rinse fluid only or combined solvent, rinse and spin chambers with one or more high flow nozzles.

18. The system of claim 1, wherein the high flow dispensing arm can be used for 3D structures bonded to wafers, panels and circuit boards of varying sizes semi-standard or non-standard dimensions.

19. The system of claim 1, wherein the fluid comprises gaseous N2 and the substrate is spinning during dispensing of the high flow N2 from the nozzle.

20. The system of claim 1, wherein the fluid comprises gaseous N2 and the substrate is in a fixed position.

21. The system of claim 20, wherein the high flow gaseous N2 can be dispensed in a pattern that traces the edge of interposer or die edges to displace fluid from between and surrounding bumps that comprises the 3D structures.

22. The system of claim 1, wherein the fluid comprises a liquid that when dispensed turns into a gas under the conditions within the spin processing chamber.

23. A system for improving yield and increasing throughput on processes that remove flux and flux residues from openings between 3D semiconductor structures, the system comprising:
a processing chamber; and
a dispensing arm that discharges high flow, directed, pressurized nitrogen to assist in de-wetting areas between the 3D semiconductor structures where solder bumps or micro bumps attach one 3D semiconductor device to another.
